(19) United States
(12) Patent Application Publication
(10) Pub. No.: US 2023/0189542 A1
(43) Pub. Date: Jun. 15, 2023

(54) COLLOIDAL QUANTUM DOT LIGHT EMITTERS AND DETECTORS

(71) Applicants: UNIVERSITEIT GENT, Gent (BE); IMEC VZW, Leuven (BE)

(72) Inventors: Lukas ELSINGER, Jersey City, NJ (US); Zeger HENS, Gent (BE); Dries VAN THOURHOUT, Gent (BE)

(21) Appl. No.: 17/922,024

(22) PCT Filed: Apr. 30, 2021
(86) PCT No.: PCT/EP2021/061426

§ 371 Date: Oct. 28, 2022

(30) Foreign Application Priority Data
Apr. 30, 2020 (EP) 20172462.2

(51) Int. Cl. H10K 50/115; H10K 50/858; H10K 50/16; H10K 50/15; H10K 85/50; H10K 71/16

(52) U.S. Cl. CPC H10K 50/115; H10K 50/858; H10K 50/16; H10K 50/15; H10K 85/50; H10K 71/16; B82Y 20/00

(57) ABSTRACT

An integrated optoelectronic device includes a substrate which supports a passive waveguide for index-confining, in two transverse directions, and guiding, along a longitudinal direction, at least one optical mode. The devices further include a first charge transport layer for transporting charge carriers of a first conductivity type, a second charge transport layer for transporting charge carriers of a second conductivity type, opposite to the first conductivity type, and an active layer comprising a particulate film of solution-processable semiconductor nanocrystals. The active layer is arranged relative to the charge transport layers to form a diode junction. The active layer and the first and the second charge transport layer are further formed on the substrate such that they each overlap at least a portion of the waveguide in a cross-section perpendicular to the longitudinal direction. The active layer is evanescently coupled to the waveguide.

### FIELD OF THE INVENTION

The present invention relates to the field of light-emitting and light-detecting devices, and in particular to light emitters and photodetectors for photonic integrated circuits that are based on solution-processable semiconductor materials such as colloidal quantum dots.

### BACKGROUND OF THE INVENTION

Owing to their simplified and less expensive manufacture, optoelectronic devices that are based on a solution-proces sable active material such as colloidal quantum dots (QD) have the potential of replacing today's commonly used and epitaxially grown counterparts. Although the feasibility of an electrically pumped laser diode using a colloidal quantum dot layer as gain material has long been doubted, recent research efforts have led to the development of specifically engineered colloidal quantum dots (QDs) that offer reduced Auger recombination rates and hence are promising candidates for the realization of the long-sought QD laser diode.

Lim, J., et al. “Optical gain in colloidal quantum dots achieved with direct-current electrical pumping”, Nature Mater. 17, 42-49 (2018), propose that chemically synthesized semiconductor QDs could enable solution-processable laser diodes. Continuously graded QDs were used in an electroluminescence device with p-i-n architecture to achieve population inversion and optical gain with direct-current electrical pumping. A thin active QD layer has been sandwiched between electron and hole transport layers and a specially shaped dielectric LiF spacer has been provided as a template for fabricating a tapered hole injection layer. A narrow (70-100 μm width) contact area with the QD emitting layer is obtained with such a current-focusing architecture. Current densities of up to ˜18 A cm⁻² have been measured without damaging either the QDs or the injection layers.

For this approach, a disadvantage is that an optical cavity adequate for electrically pumped lasing is lacking. Moreover, an additional spacer is necessary for shaping the contacted portion of the hole injection layer to small contact areas.

In Roh, J. et al. “Optically pumped colloidal-quantum-dot lasing in LED-like devices with an integrated optical cavity”, Nat. Commun. 11, 271 (2020), these specially engineered QDs are used to implement a multilayered p-i-n structure with dual functionality: being operated as a light emitting diode (LED) if an additional p-type contact electrode is provided on top of the p-i-n structure or an optically pumped laser if the p-type contact electrode is removed. They propose an optical cavity in which a distributed feedback resonator is directly integrated into a bottom low refractive index ITO (L-ITO) cathode of the multilayer stack. The optical mode is weakly confined by an ultrathin quantum dots comprising active layer.

A disadvantage of this approach is that a careful engineering of the refractive-index profile across the device is required to obtain the weak optical confinement of a waveguided mode within the QD medium. A non-standard mixture of ITO and silica is necessary to guarantee sufficiently stable mode guiding in the very thin active layers that are mandatory for electrically pumped lasing. The maximum current density demonstrated in these devices is limited to 0.2 A cm⁻², too small to achieve lasing threshold by electrical injection.

There is thus still a need for efficient optoelectronic devices, in particular for laser diodes, which are made from solution-processable active materials.

### SUMMARY OF THE INVENTION

It is an object of embodiments of the present invention to provide efficient optoelectronic device structures that support high injection current densities in an active layer comprising solution-processable semiconductor nanocrystal material and that also support low loss optical mode guiding.

It is a further objective to embodiments of the present invention to provide optoelectronic device structures which guide and confine an optical mode in a robust and reliable manner, independent of a thickness of the active layer comprising solution-processable semiconductor nanocrystal material, in particular of a thin film active layer that is invertible under a DC bias current.

The above objective is accomplished by a method and devices according to the present invention.

The invention relates to an integrated optoelectronic device which comprises a substrate, a first charge transport layer for transporting charge carriers of a first conductivity type, a second charge transport layer for transporting charge carriers of a second conductivity type, opposite to the first conductivity type, and an active layer comprising a thin particulate film of solution-processable semiconductor nanocrystals, e.g. a particulate film (monolayer, bilayer, multilayer) of colloidal quantum dots. The substrate is supporting a passive waveguide for guiding light along a longitudinal direction of the device (the optical axis) and index-confining the guided light, into at least one optical mode, in each transverse direction of the device. The active layer is arranged relative to said charge transport layers to form a diode junction. The active layer and the first and the second charge transport layer are formed on the substrate and each overlap at least a portion of the waveguide in a cross-section perpendicular to a propagation direction of the at least one optical mode in said waveguide. The active layer is optically coupled to the waveguide. The waveguide is typically a non-planar waveguide, e.g. non-slab, meaning that the transverse index-confinement obtainable with that waveguide is two-dimensional and allows the optical axis of the waveguide to bend, i.e. the longitudinal direction of the waveguide may vary with respect to the substrate that is supporting the waveguide. In any event, the two transverse directions of the waveguide correspond to the two smaller dimensions of the waveguide, typically featuring sub-micron length scales, whereas the longitudinal direction of the waveguide corresponds to the optical axis of the waveguide and extends over distances much larger than the two transverse dimensions of the waveguide. In other words, the waveguide realizes index confinement of the at least one optical mode in a first transverse direction, parallel to the charge transport layers and the active layer and in a second transverse direction, perpendicular to the charge transport layers and the active layer, wherein both the first and the second transverse direction are perpendicular to the longitudinal direction.

In contrast to conventional III/V semiconductor devices like laser diodes, in which the lower bandgap materials have higher refractive index to allowing optical mode confinement in the active region and in which bandgap and refractive index are routinely tuned by changing the composition, active layers based on solution-processed semiconductor nanocrystal materials are incompatible with these established design principles. The main reason is that, with the commonly available different organic and inorganic charge transport layers, the available current density injected into the active layer is limited and it is thus not possible invert thick active layers based on solution-processed semiconductor nanocrystal materials, which would allow for a sufficient mode confinement. The present invention provides a solution to these issues by having the optical mode index-confined by the waveguide and having the mode overlap with the active layer.

In embodiments of the invention, an average interparticle distance between adjacent particles of the active layer particulate film may be less than 10 nm, e.g. less than or equal to 5 nm, resulting in a dense assembly of particles (e.g. closely packed) in the active layer particulate film. The active layer particulate film is typically discontinuous, i.e. does not contain a continuous-phase host material in which the semiconductor nanocrystal particles are embedded. Preferably, a nanoparticle surface density in respect of the active layer particulate film is larger than 1.0*10¹¹ cm⁻², e.g. larger than 1.0*10¹² cm⁻², e.g. 5.0*10¹² cm⁻² or more.

In embodiments of the invention, the optoelectronic devices may be configured to operate as a light-emitting device, e.g. laser diode, LED, or semiconductor optical amplifier, a light-detecting device, e.g. photodetector, or light-modulating device, e.g. electro-optical modulator.

In embodiments of the invention, the optoelectronic device may be provided as a photonic integrated circuit (PIC). They therefore have the advantage of being miniaturized devices, mass-producible, at wafer scale, and low-cost. Solution-processed semiconductor nanocrystal material are compatible with a large variety of passive waveguide platforms. In contrast to conventional III/V semiconductor active devices, the solution-processed materials of the active layer do not rely on costly and complex epitaxial growth environments and can be obtained at lower temperatures.

In embodiments of the invention, the solution-processable semiconductor nanocrystal material of the active layer comprises one or more of the of the group of colloidal quantum dots, nanocrystal perovskite-based material, bulk-like semiconductor crystals and nano-platelets. Semiconductor nanocrystal materials like colloidal quantum dots are attractive for the large material gain and wavelength tunability.

In embodiments of the invention, a current path through the first charge transport layer, the active layer and the second charge transport layer may not extend into the waveguide. This has the advantage that free carrier induced absorption modal losses can be reduced.

In embodiments of the invention, the active layer may be evanescently optically coupled to the waveguide by mode overlap between the at least one guided optical mode confined in the waveguide and the active layer. A confinement factor for the at least one guided mode in the active layer can be engineered in function of waveguide geometry and material, and active layer distance. This has the advantage that the saturation power of the optoelectronic device can be controlled.

In embodiments of the invention, the waveguide may be configured for confining and guiding said at least one optical mode independently of the active layer. The confinement of the at least one optical mode is an index confinement governed by the waveguide. Thickness variations and/or distance variations of the active layer with respect to the waveguide thus do not result in the loss of optical confinement and waveguiding in the device. In general, the optical waveguide is a non-planar waveguide, for instance a rib waveguide or ridge waveguide. Moreover, an optical waveguide supporting only a single guided mode, or only a few guided optical modes (e.g. three guided optical modes or less) is preferred.

In embodiments of the invention, a contacted portion of the active layer may overlap the waveguide in said cross-section. This is further advantage because electrical confinement and charge carrier recombination can take place in close proximity to the location of peak intensity of the guided at least one optical mode, which improves an internal quantum efficiency of the device.

In embodiments of the invention, the first charge transport may be an organic semiconducting hole transport layer and the second charge transport layer an inorganic semiconducting electron transport layer. The first and the second charge transport layer, the active layer, and the waveguide may be vertically stacked in said cross-section. This has the advantage that the second charge transport layer can also act as a bottom contact of the diode junction. No further bottom contact layers (cathode) is thus required, which allows to reduce carrier induced modal losses. Moreover, no additional layers, such as adhesive layers or bonding layers, are required in the vertical stack between the waveguide and the active layer. This has the advantage that modal losses can be reduced and/or that an improved modal overlap with the active layer is obtained, which reduces the laser threshold current density in laser diodes using the optoelectronic device according to such embodiments.

In embodiments of the invention, the second charge transport layer may be a semiconducting electron transport layer provided between the active layer and the waveguide. A semiconducting electron transport layer may be optimized for good electron mobility, good conductivity, and reduced optical losses. This has the advantage that modal losses of the at least one guided mode arising near the waveguide are further reduced. This can be further improved by providing a thicker first charge transport layer so that a top contact electrode is farther located from the waveguide and the optical mode guided therein.

In embodiments of the invention, the second charge transport layer may conform to the contour of the waveguide, the waveguide rising from a surface of the substrate. This has the advantage that charge carrier recombination or generation takes place in close proximity to the waveguide and the peak intensity of the at least one guided optical mode. In consequence, an internal quantum efficiency of the device can be increased. Moreover, good current focusing is obtained in such embodiments at the active layer, allowing larger current densities to be injected or extracted from the active layer, and further enabling inversion of thin film active layers comprising solution-processed semiconductor nanocrystal material by DC current biasing.

In embodiments of the invention, the first and the second charge transport layer may be coplanar and arranged to overlap with different portion of the waveguide in said cross-section such that adjacent edges of the first and the second charge transport layer are separated by a gap and the active layer extends at least over a portion of the first and the second charge transport layer and into the gap. The waveguide may be a slotted waveguide such that the gap extends between two waveguide rails of the slotted waveguide. It is an advantage of such embodiments that an increased modal overlap with the active layer can be obtained and that electrical fields associated with the at least one guided optical mode are relatively uniform within the gap.

In another aspect the invention relates to an integrated light-emitting device, in particular an integrated light-emitting diode (LED) or an integrated laser diode (LD), including the integrated optoelectronic device according to embodiments of the previous aspect. In embodiments of this aspect, the optical waveguide is evanescently coupled to a light-emitting layer stack of the integrated light-emitting device, e.g. the light-emitting layer stack of the LED or LD, which contains the active layer and the charge transport layers. This light-emitting layer stack is typically oriented vertically with respect of the waveguide-bearing substrate, i.e. perpendicularly to a top surface of the waveguide and layers of the light-emitting layer stack being coplanar with the waveguide comprising plane (e.g. substrate layer).

In a further aspect, the invention may also relate to an integrated photodetector (PD) including the integrated optoelectronic device according to embodiments of the first aspect. The photodetector further comprises a first electrode in electrical contact with the first charge transport layer and a second electrode in electrical contact with the second charge transport layer for inducing a reverse biasing condition across the diode junction, wherein the active layer is adapted for generating charge carriers of opposite conductivity charge under said reverse biasing condition, and wherein the diode junction is adapted for separating and collecting the generated charge carriers into the corresponding charge transport layers under said reverse biasing condition. In embodiments of this aspect, the optical waveguide is evanescently coupled to a light-absorbing layer stack of the integrated PD, which contains the active layer and the charge transport layers. This light-absorbing layer stack is typically oriented vertically with respect of the waveguide-bearing substrate, i.e. perpendicularly to a top surface of the waveguide and layers of the light-emitting layer stack being coplanar with the waveguide comprising plane (e.g. substrate layer).

In yet a further aspect, the invention relates to a method for decoupling charge current injection and index confinement of a guided optical mode in an active layer of an integrated optoelectronic device. The integrated optoelectronic device comprises a first charge transport layer for transporting charge carriers of a first conductivity type, a second charge transport layer for transporting charge carriers of a second conductivity type, opposite to the first conductivity type, and an active layer comprising a solution-processed semiconductor nanocrystal material. The active layer is arranged relative to said charge transport layer to form a diode junction. The method comprises the steps of providing a substrate supporting a passive waveguide for index-confining and guiding light in at least one optical mode, while being optically coupled to the active layer. The index-confinement is obtained for the two transverse directions of the elongated waveguide body, e.g. width and height direction of the waveguide, whereas the confined light in the at least one optical mode is guided in a longitudinal direction, corresponding to the preferred direction of elongation of the waveguide. The method further includes the step of arranging each one of the active layer, the first charge transport layer and the second charge transport layer on the substrate so as to overlap at least a portion of the waveguide in a cross-section perpendicular to the longitudinal direction of confined light propagating along the waveguide.

It is an advantage of these decoupling methods that low-loss passive waveguides can be combined with high material gain, thin film active layers without compromising a reliable optical guiding in the waveguide. Moreover, this offers a more flexible design approach which helps reducing the mode overlap with, or mode leakage into, lossy contact layers. This is in contrast with prior art lasing devices based on solution-proces sable semiconductor nanomaterials, in which combined index-confinement and charge carrier injection is realized in a single active layer of the device stack. In these prior art devices there exist conflicting requirements on the active layer thickness. On the one hand, relatively thin active layers are necessary to obtain efficient charge carrier injection at rates that enable population inversion and lasing. On the other hand, relatively thick active layers are preferred in view of their better index-confinement and modal gain properties of the guided optical mode, e.g. the light is guided more reliably without leaking to a large extent into the surrounding layers, in particular of metal contact and charge transport layers with high optical losses, whereby the lasing threshold is increased too significantly to still be obtainable by pure electrical pumping.

A last aspect of the present invention is directed to a method of manufacture for an integrated optoelectronic device according to any one of the embodiments relating to the first aspect. The method comprises providing a substrate with a passive waveguide and forming a layer stack by sequentially depositing on said substrate, in the following order:
(i) a second charge transport layer for transporting charge carriers of a second conductivity type,
(ii) an active layer comprising a particulate film of semiconductor nanocrystals, wherein the semiconductor nanocrystals are deposited from solution, and
(iii) a first charge transport layer for transporting charge carriers of a first conductivity type on the substrate, opposite to the second conductivity type.

In accordance with the inventive method, the waveguide is configured for guiding light along a longitudinal direction and for index-confining, in at least one guided optical mode, the guided light in each transverse direction. Moreover, each of the deposited active layer and the deposited first and the second charge transport layer overlaps at least a portion of the waveguide in a cross-section perpendicular to the longitudinal direction (i.e. propagation direction of light in the waveguide). The active layer is arranged relative to the two charge transport layers to form a diode junction and the active layer is evanescently optically coupled to the waveguide.

According to preferred embodiments, the deposited first charge transport layer is an organic layer and the deposited second charge transport layer is an inorganic layer. Depositing the first charge transport layer may include vacuum thermal evaporation or organic vapor phase deposition, while depositing the second charge transport layer may include thermally controlled atomic layer deposition (ALD), with or without assistance by a reactive plasma (plasma-assisted ALD). In particularly preferred embodiments, depositing the second charge transport layer includes depositing a nanometric layer of polycrystalline zinc oxide (ZnO), using atomic layer deposition at substrate temperatures between 60° C. and 300° C., and optionally a subsequent annealing step at about 400° C. Annealing may be performed in a nitrogen or hydrogen atmosphere. A plasma- or radical-assisted atomic layer deposition process may be used with the additional advantages of, among others, reduced temperature processing, greater process flexibility (e.g. regarding the choice of precursors and their reactivity), reduced purge times, precursor ligand removal, improved film properties, and increased film growth per deposition cycle.

According to preferred embodiments, deposition of the semiconductor nanocrystals of the active layer from solution includes subjecting a dispersion of preformed semiconductor nanocrystals, e.g. pre-synthesized colloidal core-shell quantum dots, to a wet processing technique, such as spin-coating, dip-coating, spray-coating, Langmuir-Blodgett or Langmuir-Schaeffer deposition, or inkjet printing.

In accordance with some embodiments of the invention, the second charge transport layer may be deposited directly onto the waveguide to obtain an overcoated waveguide. Furthermore, the method may include depositing a cladding material at both sides of the overcoated waveguide, whereby the second charge transport layer is passivated, and planarizing the deposited cladding material such that a top surface of the deposited cladding material is flush with a top surface of the overcoated waveguide. Additionally, one or more of the following steps may be carried out: contacting the first charge transport layer with a first metal electrode, contacting the second charge transport layer with a second metal electrode, and encapsulating the integrated optoelectronic device.

Embodiments of the invention have the advantage that the semiconductor nanocrystals of the active layer particulate film can be obtained from solution, which is more versatile and cheaper as compared to epitaxial growth methods, e.g. molecular beam epitaxy. For instance, solution-processing of semiconductor nanocrystals allows monolayer or multilayer deposition even onto irregular or patterned surfaces, as well as onto amorphous surfaces. Moreover, much denser particulate films can be obtained compared with conventional epitaxial growth methods and a host material is not required.

Embodiments of the invention also have the advantage that integrated optoelectronic device can be manufactured more easily, not requiring an additional intermediate layer bonding step between two wafers or between a wafer and a die. In consequence, a relatively thick intermediate bonding layer, e.g. adhesive layer, with respect to the waveguide dimensions (in particular height) can be avoided, whereby mode overlap and evanescent coupling efficiency between the waveguide optical mode and the active layer is improved. In case of conductive intermediate bonding layers, eliminating the intermediate bonding layer leads to lower series resistance along the current path and increases the current density attainable of charge carriers upon injection into the active layer.

Integrated optoelectronic device manufacture without bonding is also preferable from the perspective of alignment and overall device compactness, because bonding is not self-aligned and usually requires broad design tolerances. The bonding of patterned mesa also often leads to larger overall devices, hampering dense integration of compact optoelectronic devices on a chip. Moreover, the epitaxially grown materials of a mesa to be bonded are typically involving a higher cost as compared to the solution-processed semiconductor nanocrystals of the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

The above and other aspects of the invention will be apparent from and elucidated with reference to the embodiment(s) described hereinafter.

### BRIEF DESCRIPTION OF THE DRAWINGS

The invention will now be described further, by way of example, with reference to the accompanying drawings, in which:

FIG. 1 is a cross-sectional view of an integrated optoelectronic device according to a first embodiment of the invention, comprising a vertical diode junction and a strip waveguide flush with a substrate.

FIG. 2 is a cross-sectional view of an integrated optoelectronic device according to a second embodiment of the invention, comprising a horizontal diode junction and a slotted waveguide.

FIG. 3 is a cross-sectional view of an integrated optoelectronic device according to a third embodiment of the invention, comprising a horizontal diode junction and a strip waveguide.

FIG. 4 is a cross-sectional view of an integrated optoelectronic device according to a fourth embodiment of the invention, comprising a vertical diode junction and a ridge waveguide rising from a substrate.

FIG. 5 is a perspective view of the embodiment shown in FIG. 4.

FIG. 6 to FIG. 11 illustrate examples of optical feedback means which can be used in integrated optoelectronic devices according to embodiments of the invention.

FIG. 12 shows the spatial mode profile of the fundamental waveguide mode in a cross-section of the integrated optoelectronic device according to the embodiment of FIG. 4.

FIG. 13 shows the spatial mode profile of the fundamental waveguide mode obtained from FIG. 12 by removing the active layer.

The drawings are only schematic and are non-limiting. In the drawings, the size of some of the elements may be exaggerated and not drawn on scale for illustrative purposes. The dimensions and the relative dimensions do not necessarily correspond to actual reductions to practice of the invention.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, directional terminology such as top, bottom, front, back, under, over and the like in the description and the claims is used for descriptive purposes with reference to the orientation of the drawings being described, and not necessarily for describing relative positions. Because components of embodiments of the present invention can be positioned in a number of different orientations, the directional terminology is used for purposes of illustration only, and is in no way intended to be limiting, unless otherwise indicated. It is, hence, to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art.

In the description provided herein, numerous specific details are set forth. However, it is understood that embodiments of the invention may be practiced without these specific details. In other instances, well-known methods, structures and techniques have not been shown in detail in order not to obscure an understanding of this description.

### DEFINITIONS

When reference is made to a solution-processed material, what is meant is a material that has been obtained from a wet chemical environment, e.g. a solution, by any deposition technique that is forming part of the state of the art. Known deposition techniques from solution include spin-coating, evaporation, centrifugation, sol-gel processes, inkjet printing, screen printing, spray coating, and precipitation, but are not limited thereto. It is a distinct advantage of solution-processable materials over epitaxially grown materials that they can be deposited onto amorphous solid-state interfaces.

When reference is made to a nanocrystal material, what is meant that the material is composed of particles all three dimensions of which are not exceeding 100 nm. In particular, quantum dots refer to particles which are typically not larger than 20 nm in each spatial direction. More generally quantum dots refer to nanometer-sized crystals that show quantum confinement effects in all three spatial dimensions for the charge carriers of at least one conductivity type.

In the context of the present invention, when a layer is said to be overlapping or in overlap with a portion of the waveguide in a given cross-section, then a projected surface of that layer in a direction perpendicular to that layer includes a projected surface of that portion of the waveguide along the same direction, which portion also contains the cross-sectioning plane.

In a first aspect the present invention relates to an integrated optoelectronic device. According to embodiments of the invention, the optoelectronic device structure can be adapted to primarily function as a light-emitting device, e.g. semiconductor laser diode (LD) or semiconductor light-emitting diode (LED), a light-amplifying device, e.g. semiconductor optical amplifier (SOA), light-detecting device, e.g. photodiode or wavelength-resolving photodetector, or light-modulating device, e.g. electro-optical modulators based on electro-absorption effects (e.g. quantum-confined Stark effect) or on electro-refractive effects (e.g. Pockels effect). Optoelectronic devices according to embodiments of the invention are integrated devices that are manufacturable as wafer-scaled photonic integrated circuits. It is therefore an advantage of embodiments of the invention to provide low-cost, mass-producible and compact optoelectronic devices with different functionalities, including emission of light, lasing, light amplification and light detection. Integrated optoelectronic devices according to embodiments can be combined on a same integrated photonic chip to provide more versatile circuits, e.g. a lasing device coupled to a modulator or a photodiode comprising a pre-amplification stage.

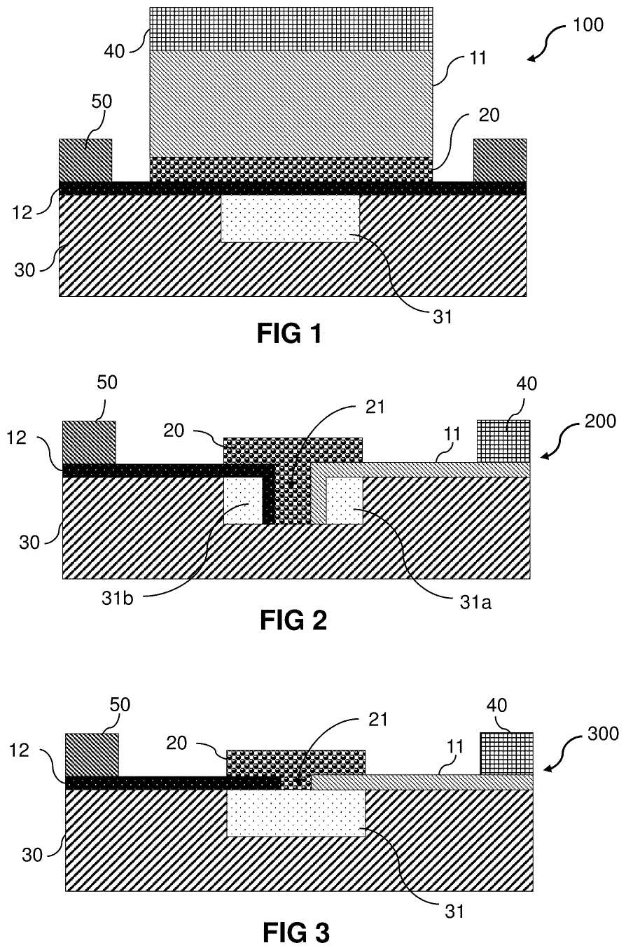

FIG. 1 is a cross-sectional view of an integrated optoelectronic device according to a first embodiment. The optoelectronic device 100 comprises a substrate 30 and formed therein an optical waveguide 31 such that a top face of the waveguide levels with a top surface of the substrate. The waveguide is configured for guiding at least one optical mode in a direction perpendicular to the cross-section. A vertical layer stack is formed over the waveguide comprising region of the substrate, which includes, in the order from the top to the bottom of the stack, a contact layer forming first electrode 40, a first charge transport layer 11, an active layer 20 comprising a solution-processed semiconductor nanocrystal material, and a second charge transport layer 12. Second charge transport layer 12 and substrate 30 are arranged contiguously at least where the waveguide 31 is formed in the substrate 30, i.e. the second charge transport layer is in physical contact with the top face of the waveguide. A second electrode 50 is provided as a pair of electrodes that are electrically contacting the second charge transport layer 12.

The vertical layer stack has the structure of and operates according to a p-i-n diode. In consequence, the integrated optoelectronic device 100 may be selectively operated as a light-emitting device, e.g. laser diode, or a light-detecting device, depending on the selected biasing regime of the diode structure comprised by the optoelectronic device: forward biasing the diode structure results in the emission of light, whereas reverse or zero-biasing of the diode structure results in the absorption of light. More specifically, the active layer 20 is arranged between the first charge transport layer 11 and the second charge transport layer 12 such that, under forward biasing conditions, the majority charge carriers, pumped into and transported by the respective charge transport layers 11, 12, are efficiently injected into the active layer and recombine therein, thereby generating light. In contrast thereto, light is absorbed in the active layer 20 under reverse or zero biasing conditions, thereby generating an electron-hole pair which is then separated into the majority carriers of the first and second charge transport layer 11, 12. Those of ordinary skill in the art will appreciate that the layer thicknesses of and specific material choices for the active layer 20 and the two charge transport layers 11, 12 very much depend on the intended use of the optoelectronic device, it lies within the routine work of the skilled artisan to select materials and optimize the layer thicknesses in accordance with the device function, e.g. to realize a light-emitting or light-amplifying devices (LDs, LEDs, SOAs), a photodetector, or an optical modulator.

As the presence of the waveguide precludes the possibility of forming a straightforward backside contact to the vertical layer stack, side contacting of the vertical layer stack by the laterally offset electrode pair 50 is preferred. This has the advantage that all the electrical contacts are provided at a same device side, and further that the second electrode 50 can be formed close to the diode structure of the vertical stack, which reduces resistive heating losses. In the present embodiment, lateral charge transport towards the vertical layer stack is accomplished by the second charge transport layer 12 too. No additional contacting layer is thus required for electrically contacting the bottom side of the vertical layer stack. High current densities can be obtained in the active layer by limiting a lateral extent of the vertical layer stack, a prerequisite for reaching population inversion and lasing in a semiconductor laser diode comprising the optoelectronic device according to the present embodiment. Moreover, having the pair of conductive electrodes 50 laterally offset also reduces the contribution of free carrier induced optical losses in the waveguide 31. Although the vertical layer stack is shown to be centered with respect to the waveguide 31 in FIG. 1, it may also be positioned asymmetrically relative to the waveguide. The optoelectronic device 100 is thus robust against misalignments during the fabrication stage, e.g. misalignments during lithography. As an alternative to the first electrode 40 forming a flat top electrode layer, the first electrode 40 may also be patterned, e.g. into the shape of two parallel coplanar stripe electrodes. Despite the additional patterning step, such an electrode configuration has the advantage that metal-induced propagation losses for a guided optical mode in the waveguide are further reduced.

Referring now to FIG. 2, a cross-sectional view of an integrated optoelectronic device 200 according to a second embodiment of the invention is depicted. In this embodiment, the waveguide is arranged as a slotted waveguide that is composed of two waveguide rails 31a, 31b separated by a gap 21. The first charge transport layer 11 is formed contiguously on the substrate surface on only one side of the waveguide, e.g. where the first waveguide rail 31a is located, and the second charge transport layer 12 is formed contiguously on the substrate surface on only the other one side of the waveguide, e.g. where the second waveguide rail 31b is located. Both the first and the second charge transport layers 11, 12 extend into the gap 21, without however touching one another, such that the gap-facing side wall of each one of the two waveguide rails 31a, 31b is covered by a respective one of the first and second charge transport layer. The remaining gap portion not filled by the charge transport layers contains the active layer 20. First and second electrodes 40, 50 are provided distantly from the waveguide and are electrically contacting the first and second charge transport layer 11, 12 respectively. As illustrated in FIG. 2, the active layer 20 may have a gap filling portion where it is contained in the gap 21 and an expanded portion where it is not contained in the gap 21. Together, the expanded portion and the gap filling portion of the active layer 20 have a T-shaped appearance in the cross-sectional view. It is an advantage of the present embodiment that the active layer has a gap filling portion extending into the gap between the slotted waveguide as this enlarges the mode overlap with the active layer. Furthermore, the electric field of the fundamental mode supported by the slotted waveguide is relatively uniform in the gap region as compared to the strongly decreasing evanescent tail above a ridge waveguide, for instance. The expanded portion may overlay the two charge transport layers 11, 12, e.g. to a lateral extent corresponding to the lateral dimensions of the waveguide 31a-b. The thickness (e.g. height) of the overgrown expanded portion can be controlled. This has the advantage that a contacted portion of the active layer can exists also outside the gap, whereby the unit gain or unit absorption coefficient is moderately increased without having a simultaneous increase in the width of the active layer inside the gap, i.e. without significantly altering the current densities supported by the diode structure in the gap region. Besides, in the present embodiment the two charge transport layers 11, 12 and the active layer 20 sandwiched therebetween form a horizontal p-i-n diode junction, e.g. a diode junction with a junction plane oriented perpendicular to the substrate, illustrating that layer stacks are not limited to vertical stack configurations. Good electrical confinement for concentrated charge carrier recombination is achieved automatically by means of the gap, which can be shallow relative to a longitudinal extent of the optoelectronic device. Therefore, high current densities in a narrow gap filling portion of the active layer are obtainable, a prerequisite for reaching population inversion and lasing in a semiconductor laser diode comprising the optoelectronic device according to the present embodiment.

FIG. 3 is a cross-sectional view of an integrated optoelectronic device 300 according to a third embodiment of the invention, which is similar to the second embodiment of FIG. 2, but in which the waveguide 31 is provided as a strip waveguide. In consequence, the gap 21 is not provided in a natural manner by the waveguide structure itself. For the present embodiment, the gap 21 is defined as the separating space (e.g. elongated aperture, slit) extending between the first and the second charge transport layer 11, 12, each being formed contiguously on the substrate surface on only one side of the waveguide 31. The gap 21 is filled by the active layer 20 which extends over a portion of the first and second charge transport layers 11, 12 on each side of the gap 21, e.g. over a portion of the first and second charge transport layers 11, 12 covering the waveguide 31. Hence, the active layer 20 may have a gap filling portion where it is contained in the gap 21 and an expanded portion where it is not contained in the gap 21. Together, the expanded portion and the gap filling portion of the active layer 20 have a T-shaped appearance in the cross-sectional view. Preferably, the gap 21 is centered with respect to the waveguide 31 to symmetrically couple light from the waveguide 31 into the active layer 20, or vice versa, e.g. from the active layer 20 into the waveguide 31.

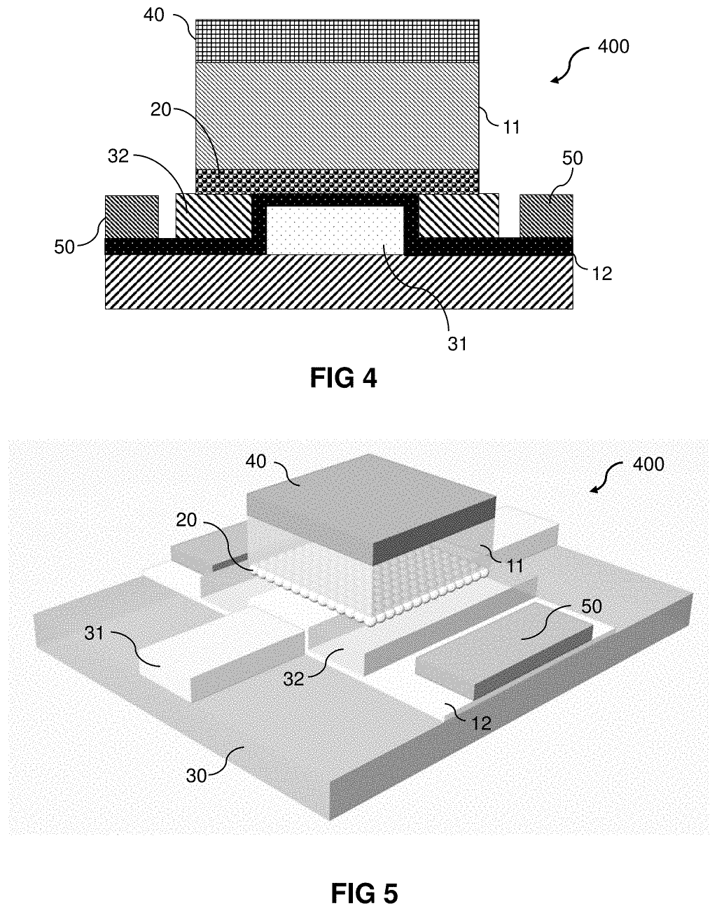

FIG. 4 shows a cross-sectional view of an integrated optoelectronic device 400 according to a fourth embodiment of the invention. It differs from the first embodiment of FIG. 1 in that the waveguide 31 is formed on the surface of the substrate 30 such that the waveguide stands out from the substrate surface. The top face of the waveguide is thus not at the same height as the surface of the substrate. Conforming to the contours of the waveguide 31, the second charge transport layer 12 covers the top and side faces of the waveguide 31 with a substantially constant layer thickness, e.g. second charge transport layer 12 is conformally coating the waveguide 31 where it rises form the substrate surface. A cladding material 32 may be provided at both sides of the waveguide 31, levelling with the coated top face thereof. The cladding material 32 may act as an additional support member with respect to the vertical layer stack provided on top of the coated waveguide rising from the substrate. It is a further advantage of the present embodiment that cladding layer 32 acts as a passivation layer for the second charge transport layer 12. An aperture may be provided in the cladding layer 32 where the second electrode 50 is electrically contacting the second charge transport layer 12, or the cladding 32 may be of limited lateral extent to achieve electrical contacting between the second electrode 50 and the second charge transport layer 12. The present embodiment is particularly suited for achieving good current focusing and high current densities in the active layer 20, because a contacted portion of the active layer 20 by the second charge transport layer 12 is limited to the lateral size (width) of the waveguide 31. A further advantage is that the waveguide 31 is located adjacent to the current injection and recombination region of the active layer, whereby light generated or absorbed in the active layer can be efficiently coupled into or out of the waveguide respectively. As an alternative to the first electrode 40 forming a flat top electrode layer, the first electrode 40 may also be patterned, e.g. into the shape of two parallel coplanar stripe electrodes. Despite the additional patterning step, such an electrode configuration has the advantage that metal-induced propagation losses for a guided optical mode in the waveguide are further reduced.

FIG. 5 is a perspective view of the integrated optoelectronic device 400 in FIG. 4. The waveguide 31 is provided as a straight waveguide, but may also have a different shape and/or a shape that varies in a longitudinal direction (e.g. the light propagation direction in the waveguide). For instance, the waveguide may be curved, s-shaped or otherwise bent in a direction of light propagation along the waveguide. The electrodes 40, 50 may be longitudinally extending to enable current delivery or extraction all along the vertical layer stack.

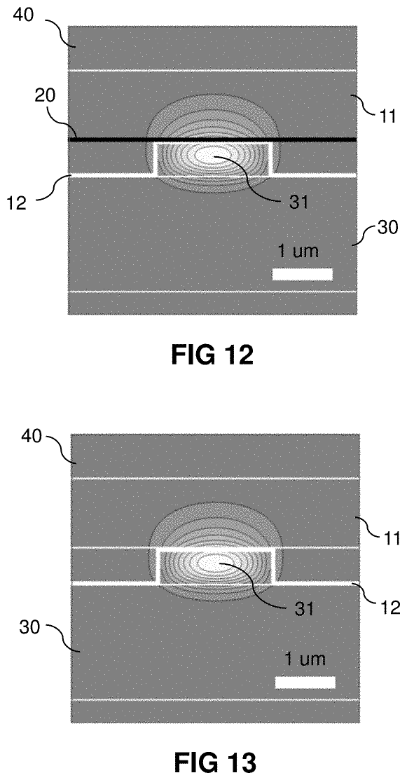

FIG. 12 shows the optical intensity distribution (mode profile) for the fundamental guided transverse-electric (TE) mode of the waveguide 31 in the embodiment of FIG. 4 and FIG. 5. This is to be compared with the optical mode profile of an identical waveguide and almost identical vertical layer stack as shown in FIG. 13, for which only the active layer has been omitted. It follows from this comparison that the optical mode profile, associated with the waveguide in absence of the active layer, is substantially unaltered if the active layer is included. In other words, the general shape and the optical properties of the waveguide and its associated optical modes, e.g. 1/e spatial extent and confinement factor, are not significantly impacted by the presence of an active layer. The overlap of the fundamental waveguide mode and the active layer in FIG. 13 enables some degree of evanescent wave coupling, e.g. the mode overlap fraction may range between 0.1% and 10% of the effective mode area.

The substrate may be an insulating or semi-insulating substrate, e.g. a silicon substrate comprising a buried oxide between the bulk silicon and a material layer for photonic integrated circuit formation and functionality, e.g. a silicon nitride layer (visible and infrared light) or silicon layer (infrared light).

The first charge transport layer 11 may be a hole transport layer and is preferably implemented as an organic hole transport layer, although inorganic hole transport layers may also be used. Typical materials for the first charge transport layer may include semiconducting OLED materials, e.g. organic molecular semiconductors having a large HUMO-LUMO energy gap, e.g. triphenylamines such as N,N′-Di(1-naphthyl)-N,N′-diphenyl-(1,1′-biphenyl)-4,4′-diamine (NPD), tetraphenylaphtacene (Rubrene) or carbazole derivatives such as Tris(4-carbazoyl-9-ylphenyl)amine (TCTA). Further, the first charge transport layer may be multilayered comprise a transport layer, e.g. hole transport layer, and an injection layer (e.g. hole injection layer) and/or a layer for band alignment or charge generation. Multilayered first charge transport layers may also comprise at least one electron blocking layer. A layer thickness of the first charge transport layer 11 may vary between tens of nanometers up to several hundreds of nanometers, e.g. up to 2 μm. A non-limiting example of a first charge transport layer comprises a three-layered charge transport layer consisting of a charge-generating layer, e.g. a layer of 1,4,5,8,9,11-Hexaazatriphenylenehexacarbonitrile (HATCN), a hole transport layer, e.g. a layer of NPD, and a hole injection layer, e.g. a layer of TCTA.

The second charge transport layer 12 may be an electron transport layer. It may be provided as a thin layer of an organic or inorganic semiconductor material, e.g. a thin layer of polycrystalline zinc oxide or a thin layer of zinc oxide nanocrystals. However, also conductive polymers or electro-deficient molecular semiconductors may be used. If in some embodiments of the invention the first charge transport layer 11 is arranged closer to the optical waveguide 31, this layer is preferably formed from a semiconductor material which combines good charge carrier mobility (e.g. low resistance) with low optical attenuation. This has the advantage of lowering the laser threshold current and power consumption. Embodiments of the invention are not limited to first charge transport layers that are directed to holes and second charge transport layers that are directed to electrons. For example, the first charge transport layer may be the electron transport layer and the second charge transport layer may be the hole transport layer.

Although in the foregoing embodiments the second charge transport layer has been described as being arranged contiguously with respect to the substrate contiguously at least where the waveguide is formed in the substrate, i.e. the second charge transport layer being in physical contact with the top face of the waveguide, this is not a limiting feature of the present invention. In alternative embodiments, a low-refractive index interlayer, having a lower refractive index as compared to the waveguide, may be interposed between the waveguide and the second charge transport layer, thus avoiding a direct physical contact. An interlayer may be used, for example, in embodiments in which it is beneficial to have a seed layer for initiating a homogenous growth of the second charge transport layer during device manufacture. Preferably such an interlayer is kept thin to retain good mode overlap with the active layer. Besides, in embodiments of the invention a waveguide may extend longitudinally beyond an active device region that comprises the active layer. This can be of advantage as it allows for shadow mask evaporation of organic hole transport layers 11 and p-metal contact electrodes 40 with a very coarse overlay accuracy.

The semiconductor nanomaterial comprising active layer 20 is arranged between the first charge transport layer 11 and the second charge transport layer 12 to from a diode junction, e.g. a planar p-i-n junction lying parallel to the substrate 30. When this diode junction is biased positively (e.g. forward biasing condition), the transported majority carriers, e.g. holes and electrons, are injected into the active layer 20 from each side and recombine subsequently, thereby generating electroluminescence. If the diode junction is biased negatively (e.g. reverse biasing condition) or is left unbiased (e.g. zero biasing condition), majority carriers originating from the active layer 20, e.g. via light absorption and electron-hole pair creation, are separated into the respective charge transport layers under the effect of the built-in electric field that exists across the diode junction. The semiconductor nanocrystal material may comprise colloidal quantum dots, nanoplatelets, nanorods, nanoflakes, or perovskite-structured materials such as Caesium lead halide perovskite nanocrystals, which may be packed into a monolayer, bilayer or multilayer thin film. Colloidal QDs may be of the core-shell type, with engineered core and shell diameters, e.g. in function of material gain and gain threshold as described in Bisschop, S., et al. “The impact of Core/Shell Sizes on the Optical Gain Characteristics of CdSe/CdS Quantum Dots”, ACS Nano 12(9), 9011-9021 (2018). Another type of colloidal QDs that can be used in embodiments of the invention are continuously graded core-shell QDs as described in the reference of Lim et al. Semiconductor nanocrystal material like colloidal QDs may be packed into a thin film active layer with fill factors reaching up to 50%, or even higher if organic ligands on the QD shells are at least partially removed. The interstices of thin film active layers not filled by semiconductor nanocrystal material like colloidal QDs are typically comprising organic ligands and air. However, in particular embodiments, colloidal QDs may also be embedded in an inorganic or polymer matrix. The optical properties of the active layer comprising solution-processed semiconductor nanocrystal material are well described by effective medium approaches, accounting for their sub-wavelength inhomogeneities. As a result, the effective refractive index of the active layer comprising solution-processed semiconductor nanocrystal material is relatively low as compared to dense bulk materials used for integrated waveguides (e.g. silicon nitride), which is also why robust index confinement in such thin film active layers is a daunting task. In contrast thereto, thicker active layers comprising solution-processed semiconductor nanocrystal material are generally not invertible by means of a DC bias current and cannot be used as electrically pumped gain media.

In a further aspect the invention relates to an integrated light-emitting device comprising or based on the integrated optoelectronic device according to embodiments of the foregoing aspect. The light-emitting device may be a light-emitting diode (LED). In contrast to a laser diode, the LED emits an incoherent and spectrally broad beam of light. The output spectrum of the LED is dictated by the electroluminescence spectrum of the semiconductor nanocrystal material of the active layer. A fraction of the spontaneously emitted photons are coupled into the waveguide of the optoelectronic device, e.g. a multimode waveguide for better photon collection efficiency. For the use as an LED a high light extraction efficiency from the waveguide is desirable to achieve good luminance levels. This may be achieved by further providing antireflection coatings at both end facets of the waveguide, or by providing a highly reflective element (e.g. broadband mirror or reflective coating) at one end portion of the waveguide and an antireflection coating at the other one end portion of the waveguide. The light-emitting device may also be a superluminescent light-emitting diode (SLED) if spontaneous emission of the active layer is coupled into the waveguide and subsequently amplified by the active layer before being emitted from the device. Moreover, a light-emitting device based on an integrated optoelectronic device according to particular embodiments may be configured as a white LED. To this end, a plurality of active device regions, each arranged according to embodiments of the optoelectronic device described hereinabove and each comprising an active layer including a different solution-processed semiconductor nanocrystal material (e.g. QDs of different diameter emitting at different wavelengths), may be provided along and coupled to a same passive waveguide.

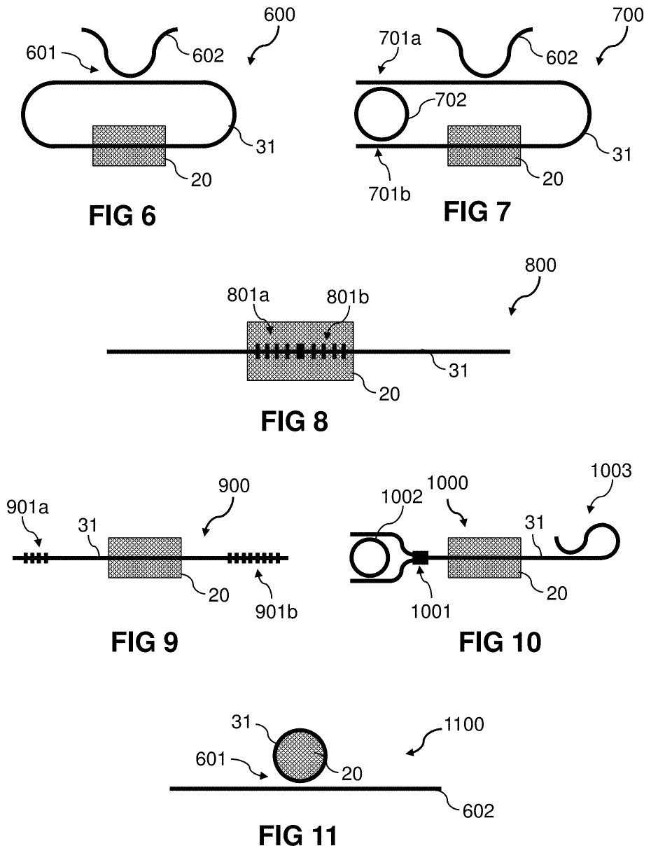

The integrated light-emission device may also be a semiconductor laser diode. To be capable of lasing, an optoelectronic device according to embodiments of the invention further comprises optical feedback means, e.g. reflectors, which are arranged relative to the active layer to form a high-quality optical cavity that includes the active layer as gain medium. The optical feedback means ensure a great number of cavity roundtrips for the intra-cavity light generated and repeatedly amplified by stimulated emission, eventually leading to a highly coherent radiation with high spectral intensity being output by the laser diode. In its simplest form the optical feedback means may be realized by cleaving the waveguide end facets. Although the achievable quality of the optical cavity formed by the cleaved waveguide is limited, this may be sufficient in some applications. Various other optical feedback means may be used for conceiving a high-quality optical cavity, further described with reference to FIGS. 6-11. Typically, the optical feedback means comprises a highly reflective first member at one side of the optical cavity and a slightly less reflective second member at the other side, i.e. the side at which light is coupled out of the cavity. The purpose of these figures is to illustrate different optical feedback means and the associated optical cavities resulting therefrom. Therefore, not all the elements of the optoelectronic devices are represented in these figures, but only the active layer 20 serving as the gain medium of the laser diode (LD), the waveguide 31 as part of the optical cavity, and the feedback means optically coupled to the waveguide for turning the cavity into a high-quality optical cavity, e.g. an optical cavity of good finesse F>>1 and/or good quality factor (Q-factor), e.g. Q>>1, e.g. Q>1000. Phase-shifters, e.g. heaters, spatial mode filters and/or converters may be provided along the waveguide 31 to tune, select and stabilize an output wavelength and/or a spatial mode profile of the LD. To enable mode-locking for a mode-locked laser diode, a saturable absorber may be provided along the waveguide 31. This saturable absorber may comprise the same solution-processed semiconductor nanocrystal material as the active layer of the optoelectronic device, but is not limited thereto.

In FIG. 6, a semiconductor LD 600 comprises a ring-shaped waveguide 31, e.g. microring resonator waveguide, which acts as the optical cavity of the LD and also provides optical feedback with respect to the active layer 20. A coupling section 601, e.g. a directional coupler, is provided along the ring-shaped waveguide 31 to couple light from the optical cavity into an output waveguide 602 of the LD. The output waveguide 602 may be provided with antireflection coatings on its end facets to prevent residual reflections from re-entering the optical cavity.

FIG. 7 is a variant of the embodiment shown in FIG. 6, in which an LD 700 comprises a curved waveguide 31 that is not circular, e.g. not implemented as a ring resonator waveguide, and which is thus not capable to provide optical feedback by itself. For the present embodiment, an additional ring resonator 702, e.g. microring resonator, is provided. It fulfills the optical feedback function by receiving light from a first end portion of the waveguide 31 via a first coupling section 701a and by feeding light back into a second end portion the waveguide 31 via a second coupling section 701b. The additional ring resonator 702 has the advantage that it can be used as wavelength filter that is incorporated into the optical cavity, e.g. it can be used as a wavelength-selective device for selecting a wavelength for lasing out of a plurality of longitudinal cavity modes.

FIG. 8 shows an LD 800 which is configured as a distributed feedback laser (DFB). A distributed reflector, e.g. a pair of Bragg reflectors 801a-b, is arranged within or adjacent to gain region of the LD 800, e.g. within or in proximity to the active layer 20. Distributed reflectors may be implemented as diffractive waveguide gratings or cladding layer corrugations, modulated doping concentration, or others. The pair of Bragg reflectors 801a, 801b may include a phase-shifting section, e.g. a π/2 or quarter Bragg wavelength shifting section. The distributed reflector acts as a wavelength-selective filter, which maximizes optical feedback for a predetermined wavelength for lasing, but suppresses optical feedback at other wavelengths, e.g. competing longitudinal cavity modes. In contrast thereto, the LD 900 of FIG. 9 is configured as a distributed Bragg reflector laser (DBR) for which the distributed reflectors, e.g. the pair of Bragg reflectors 901a-b, is arranged externally to the gain region of the LD 900, e.g. outside the active layer 20. In consequence, the DBR configuration is not influenced by changes of the current density or gain.

FIG. 10 shows an LD 1000 in which the waveguide 31 is terminated by a waveguide loop mirror 1003 at one side and, on the other side, by reflector arrangement that comprises a microring resonator 1002, two access waveguides to the microring resonator 1002 and a coupling element 1001. The two access waveguides are coupled to the microring resonator 1002 via respective coupling sections and correspond to the two outgoing branches of the coupling element 1001, e.g. a one-to-two directional coupler or multimode interferometer.

The LD 1100 shown in FIG. 11 comprises a ring-shaped waveguide 31 as the optical cavity. Compared to the LD 600 of FIG. 6, the active layer 20 of the present LD 1100 overlaps the waveguide 31 entirely. An output waveguide 602 is evanescently coupled, e.g. by coupling section 601, to the optical cavity waveguide 31 and may be provided with antireflection means to suppress external feedback re-entering the optical cavity. Alternatively, the output waveguide 602 may be used as an external cavity which provides feedback to the ring-shaped cavity. In this case, the output waveguide 602 may comprise its own reflectors.

In an integrated light-emitting device according to embodiments of the invention, multiple gain sections may be arranged along the waveguide 31, wherein each gain section has a cross-section as described hereinabove for embodiments of the invention. The solution-processed semiconductor nanocrystal material in the active layer of each of the multiple sections may be selected such that its corresponding electroluminescence spectrum partially overlaps with that of another section. This may be useful for extending the tuneable operating wavelength of the light-emitting device, e.g. laser diode, or may be used for achieving independent gain or absorption modulation in the same optical cavity.

The light-emitting diode configuration or laser diode configuration may also be used as a travelling wave SOA or Fabry Perot SOA respectively if the electrically biased below the lasing threshold. The waveguide may be tilted with respect to the cleaved facets to further reduce the impact of multiple reflection, e.g. in addition to antireflection coatings provided on the waveguide facets.

In another aspect the invention relates to an integrated photodetector. The photodetector comprises or uses any of the integrated optoelectronic devices relating to embodiments of the first aspect. The thickness and material choice of the individual layers of the optoelectronic device are preferably optimized for the targeted absorption wavelength region and detector responsivity under reverse biasing conditions. It is possible two have a multi-sectioned photodetector in which each section comprises a reverse biased optoelectronic device according to embodiments of the invention. The individual sections may be designed to absorb light of different wavelengths or wavelength bands, e.g. by adapting the quantum dot diameter or composition in the active layer of each section. A multi-section photodetector of this kind may be used in spectroscopic applications.

To operate an integrated optoelectronic device according to the preceding embodiments as a light-emitting device, the electrodes 40, 50 are connected to a power source which applies a forward bias across the diode junction. In consequence, majority carrier of opposite charge polarity are injected into the active layer 20 via the respective charge transport layers 11, 12 and recombine in the semiconductor nanocrystal material, e.g. solution-processed quantum dots, thereby generating light. The power source may be a constant-current source for controlling the current density injected into the active layer 20 and thus controlling the output light intensity of the device. A current modulation means may be provided current amplitude modulation during operation of the optoelectronic device, e.g. for obtaining gain modulation in a semiconductor laser diode. The optoelectronic device may be mounted onto a heat dissipating structure, e.g. a heat sink to avoid a large temperature increase in the device, frequently accompanied by thermal drifts in the device performance. A temperature controller, e.g. comprising a control unit and a thermoelectric cooling unit, may be provided to ensure stable temperature conditions when the device is being used.

To operate an integrated optoelectronic device according to the preceding embodiments as a light-detecting device, the electrodes 40, 50 are connected to a power source which applies a reverse bias across the diode junction. In consequence, majority carrier of opposite charge polarity are collected by the respective charge transport layers 11, 12 from the active layer 20, in which they originate as photogenerated electron-hole pairs, and are subsequently extracted from the device at the electrodes 40, 50 in the form of a photocurrent. The photocurrent may then be processed in the electrical domain, e.g. amplified and/or quantized.

Integrated optoelectronic devices according to embodiments of the invention may further be packaged according to techniques known in the art, e.g. mounting the optoelectronic device on a device carrier and wire-bonding it in a hermetically sealed, externally accessible package, e.g. butterfly package with pin connectors.

### EXAMPLE

An exemplary integrated optoelectronic device has the cross-section shown for the embodiment relating to FIG. 4. A silicon nitride strip waveguide 31, e.g. 300 nm high and 1000 nm wide, rises from an insulator-on-silicon substrate 30 and may be fabricated using standard SOI technology for PICs. Silicon nitride based dielectric waveguides typically have very low optical propagation losses, e.g. as low as 1 dB/m, and are transparent to light in the visible and infrared spectrum. Although the waveguide 31 is configured as a multimode waveguide in the present example—it guides a further higher-order TE₁ mode in addition to the fundamental TE₀ mode—in which coupling efficiency to the active layer and excess losses are balanced, other embodiments of the invention may comprise a single-mode waveguide, particularly in embodiments aiming at implanting a laser diode, although a wider multimode waveguide may also be beneficial for delivering an increased output power in high-power laser diodes. The second charge layer 12 corresponds to a thin layer of continuous semiconducting zinc oxide and is an inorganic electron transport layer. This thin layer of native n-type zinc oxide, e.g. 10 nm thick, is provided on top of the waveguide 31 and covers its contours conformally. A pair of Ti/Au/Ti (20 nm/100 nm/20 nm) metal n-contacts are formed on the zinc oxide layer and constitute the second electrode 50. Silicon oxide has been used as a side cladding material 32 to the overcoated waveguide. The top surface of the side cladding 32 is flush with the top surface of the overcoated waveguide, e.g. the top surface of the second charge transport layer 12 where it covers the waveguide 31, which provides a plane interface for the uniform deposition of the active layer 20. The active layer 20, in this example, consists of a 20 nm thick film (e.g. corresponding to two to three layers) of solution-processed, randomly oriented quantum dots, e.g. spherical colloidal CdSe/CdS core-shell quantum dots or non-spherical nanocrystals with isotropic dipole orientation. Adequate values of the core and shell diameter may be 3.5 nm and 7.5 nm respectively, for obtaining both a high intrinsic material gain, e.g. up to 2800 cm⁻¹, and a reasonably low injection current density threshold for net stimulated emission at the active layer, e.g. jₜₕ≈60 A cm⁻². Eventually, the first charge transport layer 11 has been implemented as a 600 nm thick organic hole transport layer on which a 300 nm thick aluminium p-contact is formed as the first electrode 40. More specifically, the first charge transport layer 11 consists of 70 nm TCTA (hole injection layer), 500 nm NPD (hole transport layer) and 30 nm HTA-CN (band alignment layer for holes).

Finite element simulations and finite difference time domain simulations have been carried out to optimize the waveguide geometry (e.g. width and height) and the individual layer thicknesses of the vertical layer stack with the aim of achieving good LED characteristics. The simulations were conducted for a wavelength of 650 nm, which is assumed to be the peak wavelength of the electroluminescence spectrum. These simulations are based on the refractive indices for the charge transport layers 11, 12 and the silicon nitride waveguide 31 obtained from ellipsometry measurements. Metal-induced propagation losses experienced by the fundamental waveguide mode (and all higher-order modes) in the presence of the first electrode 40 were found to be decaying exponentially fast in function of the layer thickness of the first charge transport layer. For instance, a metal-induced propagation loss of 4 dB/cm has been found by simulation for a 500 nm thick first charge transport layer and has also been validated by cut-back measurement, whereas for the 600 nm thick first charge transport layer of the present example a metal-induced propagation loss of 2 dB/cm has been estimated. The imaginary part of the complex refractive index for the zinc oxide layer has been determined as k=2.5*10⁻⁴ by means of cut-back measurements. Because of an inevitable overlap of the evanescent tail of the guided optical modes that are confined in the waveguide and the lossy zinc oxide layer additional propagation losses arise. The silicon nitride waveguide dimensions are one part of the simulation results and constitute a trade-off between overall propagation losses at the one hand and good spontaneous dipole emission coupling efficiency for the quantum dots of the active layer 20 into the waveguide 31 on the other hand. Based on the simulation results, the former were estimated as 12 dB/cm and the latter as 0.5% to 1.0% (integrated over waveguide width) for a mode overlap of about 3.6% with the active layer. The necessary material gain to overcome the propagation is approximately 880 cm⁻¹ and lies within the feasibility range of the gain-optimized core-shell quantum dots. Further, it has been found that the optimal waveguide height for a single-mode waveguide would lie in the range between 100 nm and 150 nm if only coupling efficiency is taken into account for optimization.

In the following, a way of manufacturing the integrated optoelectronic device of this example is briefly described. Starting from a bare silicon sample with a 1.0 μm thick thermal oxide layer, a 300 nm thick layer of silicon nitride is deposited by plasma enhanced chemical vapor deposition. The waveguide is defined by patterning the silicon nitride layer using electron-beam lithography with and reactive ion etching. Alternatively, a photonic integrated circuit with prefabricated waveguides, e.g. foundry-patterned silicon nitride on insulator (e.g. silicon oxide insulating layer on silicon substrate) can be provided.

Next, a 10 nm thin zinc oxide (ZnO) layer (polycrystalline, continuous) is deposited via atomic layer deposition (ALD), which conformally coats the waveguide. Deposition of the ZnO is performed at a base pressure of about 5*10⁻⁶ mbar and temperatures between 60° C. and 300° C., preferably at about 150° C., and may be assisted by a reactive plasma (e.g. oxygen and/or ozone rich plasma). The gas flow pressure of precursor (e.g. diethylzinc for zinc) and reactant materials (e.g. distilled water vapor) has been adjusted to 5*10⁻³ mbar, using needle valves. Alternative deposition techniques for the second charge transport layer, e.g. a ZnO layer, include sol-gel deposition processes or sputter deposition. Also a thin layer of ZnO nanocrystals may be deposited as an alternative, e.g. through spin coating. Thereafter, a passivation and etch-stop layer comprising 15 nm thick aluminium oxide is applied by ALD (e.g. using trimethylaluminum as a precursor and distilled water vapor as reactant), before proceeding to an optional annealing step, e.g. annealing at 400° C. maximum temperature in N₂ and H₂ atmosphere. As a result thereof, a well-performing zinc oxide layer is obtained in terms of resistance and optical losses, e.g. a sheet resistance of (1.2±0.1) kΩ/sq and free carrier absorption losses of approximately 10 dB/cm. Using diluted KOH, the passivation layer is removed locally to allow formation of the metal contacts of the second electrode (e.g. 20 nm Ti/100 nm Au/20 nm Ti) at each side of the waveguide; optical lithography and a lift-off process may be performed for this step. In a further step the zinc oxide layer beyond the device is removed through a wet-etch in dilute HCl, which is followed by chemical vapor deposition of a silicon oxide layer. This silicon oxide layer is re-opened (e.g. via electron-beam lithography, reactive ion etch and KOH wet etch to remove the etch-stop layer) to expose the zinc oxide layer in the region where the waveguide is located and in which the following layers of the vertical layer stack are to be formed. Consequently, the 20 nm thick active layer is deposited onto the exposed portion of the zinc oxide layer by using lift-off of a layer of CdSe/CdS quantum dots (e.g. oleate-capped) spin-coated from toluene. In a shadow-mask evaporation step the three organic layers (TCTA, NPD, HAT-CN) that compose the first charge transport layer are obtained under continued rotation of the sample holder. As an alternative to vacuum thermal evaporation, organic vapor phase deposition with an inert carrier gas may be used to deposit the organic charge transport layer(s). Eventually, a 300 nm thick layer of aluminium is deposited from vapor phase to form the first electrode.

A plurality of prototype integrated optoelectronic devices, each comprising a 2 mm long active device region and a ca. 1 cm long waveguide, have been manufactured in the above-described manner and tested. A current density of 47 A cm⁻² has been measured at 100 V forward bias voltage across a first device where the highest optical output power were observed. For a second device manufactured on the same chip as the first device a current density as high as 100 A cm⁻² has been obtained at 120 V forward bias voltage; even higher voltages caused failure of the device. The measured turn-on voltage for observable optical output generation by the manufactured optoelectronic devices is about 3 V. However, these measurements were limited by the noise floor of the optical power meter that has been used during testing and true electrical turn-on at about 2 V forward bias voltage is expected. The emission peak of the acquired electroluminescence spectra is located at 642 nm. A spectrally integrated optical output power of approximately 2.0 nW has been obtained in the fundamental waveguide mode of the first tested device, electrically pumped at 47 A cm⁻² current density. This corresponds to an optical power density of 1.5 W cm⁻². Higher-order modes can be filtered out efficiently by defining two single-mode waveguide portions, e.g. 450 nm wide and each 0.4 mm long, simultaneously with the multimode waveguide 31 such that they are directly connected to the multimode waveguide 31 at either end thereof. Based on the measured device output power, a maximum internal quantum efficiency of about 11% has been estimated.

A further prototype optoelectronic device (0.5 mm long) has been manufactured in the above-described manner and tested with respect to its photodetection performance. Although the prototypes have been developed for an LED use, these operate as photodetectors under reverse biasing conditions. For the photodetector characterization of the exemplary optoelectronic device light of an external LED (λ=635 nm) has been coupled into the waveguide 31. At a reverse bias voltage of −7 V, a dark current of 1.5 μA/cm² has been measured and a sub-optimal quantum efficiency of about 6% has been extracted from the measurement data. The detector quantum efficiency can be further improved by optimizing the band alignment and device processing.

In a further aspect the invention relates to a method for decoupling an active layer width from an optically confined waveguide mode in an integrated optoelectronic device, e.g. an integrated light-emitting or light-detecting device. The integrated optoelectronic device comprises a substrate, and formed on the substrate a first charge transport layer for transporting charge carriers of a first conductivity type, a second charge transport layer for transporting charges carriers of a second conductivity type, opposite to the first conductivity type, and an active layer that includes a solution-processed semiconductor nanocrystal material. The active layer is arranged relative to the first and second charge transport layer such that a diode junction is formed which is operable under a forward biasing condition or under a zero biasing or reverse biasing condition. Under the forward biasing condition the active layer is configured for generating light upon recombination of charge carriers of opposite conductivity type injected into the active layer by the respective charge transport layers. Under the zero biasing or reverse biasing condition the active layer is configured for generating charge carriers of opposite conductivity type upon absorption of light incident onto the diode junction and the diode structure is further configured for separating the generated charge carriers into the first and the second charge transport layer according to their conductivity type. The first and second charge transport layer typically are provided as n-type or p-type semiconductor layers. The decoupling method comprises providing a passive waveguide on the substrate such that in a cross-section perpendicular to a longitudinal direction of the optoelectronic device, e.g. the propagation direction of light in the waveguide, each of the first and second charge transport layer and the active layer overlaps with a portion of the waveguide. In consequence, the waveguide is provided separately from the active layer. The waveguide is configured for confining and guiding at least one optical waveguide mode, wherein the confinement is relative to the directions of the cross-section. Furthermore, a position of the waveguide relative to the active layer is adapted for mutual evanescent coupling of light between them. Evanescent coupling between the active layer and the waveguide occurs, for instance, if the at least one guided optical mode supported by the waveguide extends into the active layer and partially overlaps with the active layer. The waveguide may extend from the substrate surface into the substrate or may rise from the substrate surface. The waveguide may support a single mode or multiple modes in the cross-section. The method may further comprise the step of providing a current path to and through the diode junction, formed by the first and the second charge transport layer and the active layer, which does not pass through the waveguide. This may be obtained by arranging the waveguide relative to the diode junction such that the waveguide does not form part of the diode junction.

While the invention has been illustrated and described in detail in the drawings and foregoing description, such illustration and description are to be considered illustrative or exemplary and not restrictive. The foregoing description details certain embodiments of the invention. It will be appreciated, however, that no matter how detailed the foregoing appears in text, the invention may be practiced in many ways. The invention is not limited to the disclosed embodiments.

1.-26. (canceled)

27. An integrated optoelectronic device comprising:
a substrate supporting a passive waveguide configured for guiding light along a longitudinal direction and for index-confining, in at least one guided optical mode, the guided light in each transverse direction,
a first charge transport layer for transporting charge carriers of a first conductivity type, a second charge transport layer for transporting charge carriers of a second conductivity type, opposite to the first conductivity type,
an active layer comprising a particulate film of solution-processable semiconductor nanocrystals, the active layer being arranged relative to said charge transport layers to form a diode junction,
wherein the active layer and the first and the second charge transport layer are formed on the substrate and each overlap at least a portion of the waveguide in a cross-section perpendicular to said longitudinal direction, and wherein the active layer is evanescently optically coupled to the waveguide.

28. The integrated optoelectronic device according to claim 27, wherein individual particles of the active layer particulate film are densely packed,
wherein an average interparticle distance between adjacent particles of the active layer particulate film is less than five nanometers.

29. The integrated optoelectronic device according to claim 27, wherein a current path through the first charge transport layer, the active layer and the second charge transport layer is not extending into the waveguide.

30. The integrated optoelectronic device according to claim 27, wherein the second charge transport layer is in direct physical contact with the waveguide.

31. The integrated optoelectronic device according to claim 27, wherein an electrically contacted portion of the active layer overlaps the waveguide in said cross-section.

32. The integrated optoelectronic device according to claim 27,
wherein the first charge transport layer is an organic semiconducting hole transport layer and the second charge transport layer is an inorganic semiconducting electron transport layer, and
wherein particles of the active layer particulate film comprise one or more of the of the group consisting of: colloidal quantum dots, nanocrystalline perovskite-based material, bulk-like semiconductor nanocrystals, nano-platelets.

33. The integrated optoelectronic device according to claim 27,
wherein the first and the second charge transport layer, the active layer, and the waveguide are vertically stacked in said cross-section, and
wherein the second charge transport layer is a semiconducting electron transport layer provided between the active layer and the waveguide.

34. The integrated optoelectronic device according to claim 27, wherein the second charge transport layer conforms to the contour of the waveguide, thereby providing the waveguide with a conformal coating.

35. The integrated optoelectronic device according to claim 27, wherein the first and the second charge transport layer are coplanar and arranged to overlap with different portion of the waveguide in said cross-section, adjacent edges of the first and the second charge transport layer being separated by a gap, and the active layer extending at least over a portion of the first and the second charge transport layer and into the gap.

36. The integrated optoelectronic device according to claim 35, wherein the waveguide rises from a surface of the substrate and is configured as a slotted waveguide comprising two waveguide rails separated by a slot, the first and second charge transport layer extending into the slot.

37. The integrated optoelectronic device according to claim 27, the integrated optoelectronic device being an integrated light-emitting diode further comprising:
a first electrode in electrical contact with the first charge transport layer, and
a second electrode in electrical contact with the second charge transport layer for inducing a forward biasing condition across the diode junction,
wherein the active layer is adapted for generating light upon recombination of charge carriers of opposite conductivity type injected into the active layer by the respective charge transport layers under said forward biasing condition.

38. The integrated optoelectronic device according to claim 27, the integrated optoelectronic device being an integrated laser diode further comprising:
a first electrode in electrical contact with the first charge transport layer,
a second electrode in electrical contact with the second charge transport layer for inducing a forward biasing condition across the diode junction,
wherein the active layer is adapted for generating light upon recombination of charge carriers of opposite conductivity type injected into the active layer by the respective charge transport layers under said forward biasing condition,
optical feedback means optically coupled to the waveguide, thereby forming an optical cavity.

39. The integrated optoelectronic device according to claim 27, the integrated optoelectronic device being an integrated laser diode or integrated light-emitting diode,
wherein the diode is arranged for emitting light horizontally, in a plane parallel to the substrate, or for emitting light at an angle with respect to the substrate in an inactive region of the substrate not being covered by the active layer and the first and the second charge transport layer.

40. A method of manufacture for an integrated optoelectronic device, the method comprising the steps of:
providing a substrate with a passive waveguide, the waveguide being configured for guiding light along a longitudinal direction and for index-confining, in at least one guided optical mode, the guided light in each transverse direction, and
forming a layer stack by sequentially depositing on said substrate in that order:
a second charge transport layer for transporting charge carriers of a second conductivity type,
an active layer comprising a particulate film of semiconductor nanocrystals, wherein the semiconductor nanocrystals are deposited from solution, and
a first charge transport layer for transporting charge carriers of a first conductivity type on the substrate, opposite to the second conductivity type,
wherein each of the deposited active layer and the deposited first and the second charge transport layer overlaps at least a portion of the waveguide in a cross-section perpendicular to said longitudinal direction, the active layer is arranged relative to said charge transport layers to form a diode junction, and the active layer is evanescently optically coupled to the waveguide.

41. The method according to claim 40, wherein the deposited first charge transport layer is an organic layer and the deposited second charge transport layer is an inorganic layer.

42. The method according to claim 41, wherein depositing the first charge transport layer includes vacuum thermal evaporation or organic vapor phase deposition, and/or
wherein depositing the second charge transport layer includes thermally controlled atomic layer deposition.

43. The method according to claim 41, wherein depositing the second charge transport layer includes depositing a nanometric layer of polycrystalline zinc oxide, using atomic layer deposition at substrate temperatures between 60° C. and 300° C.

44. The method according to claim 40, wherein depositing the semiconductor nanocrystals of the active layer from solution includes performing a wet processing technique on a dispersion of preformed semiconductor nanocrystals as starting material.

45. The method according to claim 40, wherein the second charge transport layer is deposited directly onto the waveguide to obtain an overcoated waveguide, the method further comprising:
depositing a cladding material at both sides of the overcoated waveguide, wherein the second charge transport layer is passivated, and
planarizing the deposited cladding material such that a top surface of the deposited cladding material is flush with a top surface of the overcoated waveguide.

46. The method according to claim 40, further comprising:
contacting the first charge transport layer with a first metal electrode,
contacting the second charge transport layer with a second metal electrode.
